(19) United States
(12) Patent Application Publication
(10) Pub. No.: US 2025/0349374 A1
(43) Pub. Date: Nov. 13, 2025

(54) MEMORY DEVICE AND OPERATION METHOD THEREOF, MEMORY SYSTEM, AND ELECTRONIC DEVICE

(71) Applicant: YANGTZE MEMORY TECHNOLOGIES CO., LTD., Wuhan (CN)

(72) Inventors: Teng CHEN, Wuhan (CN); Dong HE, Wuhan (CN)

(21) Appl. No.: 19/184,693

(22) Filed: Apr. 21, 2025

(30) Foreign Application Priority Data
May 13, 2024 (CN) 2024105929111

(51) Int. Cl. G11C 16/34; G11C 16/24; G11C 16/26

(52) U.S. Cl. CPC G11C 16/3459; G11C 16/24; G11C 16/26

(57) ABSTRACT

A memory device includes: a memory cell array including a memory plane, wherein the memory plane includes a plurality of memory sub-planes; and a peripheral circuit coupled with the memory cell array and configured to: perform verify operations on the plurality of memory sub-planes at the same time, to obtain a verify result for the memory plane; and determine the number of fail bits of the memory plane based on the verify result.

### CROSS-REFERENCE TO RELATED APPLICATIONS

The present application claims priority to Chinese Patent Application No. 2024105929111, which was filed May 13, 2024, is titled “MEMORY DEVICE AND OPERATION METHOD THEREOF, MEMORY SYSTEM, AND ELECTRONIC DEVICE,” and is hereby incorporated herein by reference in its entirety.

### TECHNICAL FIELD

Examples of the present disclosure relate to the field of semiconductor technology, and relate to, but are not limited to, a memory device and an operation method thereof, a memory system, and an electronic device.

### BACKGROUND

Memory devices are classified into volatile memory devices and non-volatile memory devices depending on whether stored data is retained in case of power failure, wherein the non-volatile memory devices that retain the data in case of power failure may comprise a Read-Only Memory (ROM) device and a flash memory device. The flash memory device is widely used as a storage medium for portable electronic devices, such as mobile phones and digital cameras.

### SUMMARY

According to a first aspect of examples of the present disclosure, a memory device is provided, which comprises:

a memory cell array comprising a memory plane which comprises a plurality of memory sub-planes; and a peripheral circuit coupled with the memory cell array and configured to:

perform verify operations on the plurality of memory sub-planes at the same time, to obtain a verify result for the memory plane; and

determine the number of fail bits of the memory plane based on the verify result.

In some examples, the peripheral circuit comprises:

a page buffer array comprising a plurality of page buffers, wherein one of the plurality of page buffers is coupled with one of the plurality of memory sub-planes through a bit line, and each page buffer is configured to sense a fail bit current of the coupled memory sub-plane through the bit line; and

a verify counting circuit coupled with the page buffer array and configured to: obtain the verify result based on a sum of fail bit currents of the plurality of memory sub-planes; and determine the number of fail bits of the memory plane based on the verify result.

In some examples, the verify counting circuit comprises:

a reference current output circuit configured to output at least one reference current; and

a comparator, wherein a first input end of the comparator is coupled with the page buffer array, and a second input end of the comparator is coupled with the reference current output circuit; the comparator is configured to: compare the at least one reference current and the sum of the fail bit currents, and output the verify result.

In some examples, each page buffer is further configured to maintain the sensed fail bit current for a preset time period.

In some examples, the reference current output circuit is particularly configured to output the reference current after the fail bit current has been maintained for the preset time period.

In some examples, the preset time period comprises 1 microsecond.

In some examples, the page buffer comprises: a precharge circuit, wherein a first end of the precharge circuit is coupled with the bit line through a sensing node, and a second end of the precharge circuit is coupled with the verify counting circuit.

In some examples, the memory cell array comprises a plurality of memory planes; and the peripheral circuit is further configured to: select at least one memory plane from the plurality of memory planes, and perform the verify operation on the selected memory plane.

In some examples, the verify operation comprises a program verify operation or an erase verify operation.

According to a second aspect of examples of the present disclosure, an operation method of a memory device is provided, wherein the memory device comprises a memory cell array comprising a memory plane, and the memory plane comprises a plurality of memory sub-planes; the operation method comprises: performing verify operations on the plurality of memory sub-planes at the same time, to obtain a verify result for the memory plane; and determining the number of fail bits of the memory plane based on the verify result.

In some examples, the memory device further comprises a plurality of page buffers and a verify counting circuit, and one of the plurality of page buffers is coupled with one of the plurality of memory sub-planes through a bit line; the performing the verify operations on the plurality of memory sub-planes at the same time, to obtain the verify result for the memory plane comprises: sensing, by each page buffer, a fail bit current of the coupled memory sub-plane through the bit line; and obtaining, by the verify counting circuit, the verify result based on a sum of fail bit currents of the plurality of memory sub-planes.

In some examples, the determining the number of fail bits of the memory plane based on the verify result comprises: determining, by the verify counting circuit, the number of fail bits of the memory plane based on the verify result.

In some examples, the verify counting circuit comprises a reference current output circuit and a comparator, a first input end of the comparator is coupled with the plurality of page buffers, and a second input end of the comparator is coupled with the reference current output circuit; the obtaining, by the verify counting circuit, the verify result based on the sum of the fail bit currents of the plurality of memory sub-planes comprises: outputting, by the reference current output circuit, at least one reference current; and comparing, by the comparator, the at least one reference current and the sum of the fail bit currents, and outputting the verify result.

In some examples, the operation method further comprises: maintaining, by each page buffer, the sensed fail bit current for a preset time period.

In some examples, the outputting, by the reference current output circuit, the at least one reference current comprises: outputting, by the reference current output circuit, the reference current after the fail bit current has been maintained for the preset time period.

In some examples, the preset time period comprises 1 microsecond.

In some examples, the operation method further comprises: selecting at least one memory plane from a plurality of memory planes, and perform the verify operation on the selected memory plane.

In some examples, the verify operation comprises a program verify operation or an erase verify operation.

According to a third aspect of examples of the present disclosure, a memory system is provided, which comprises:

one or more memory devices as described in any example in the first aspect of examples of the present disclosure; and

a memory controller coupled to the memory device and configured to control the memory device.

According to a fourth aspect of examples of the present disclosure, an electronic device is provided, which comprises the memory system as described in the third aspect of examples of the present disclosure.

In the examples of the present disclosure, performing the verify operations on the plurality of memory sub-planes at the same time, so as to obtain the verify result for the memory plane, and determining the number of fail bits of the memory plane based on the verify result, the execution duration of Verify Failbit Count (VFC) may be reduced, which is favorable to a reduction in the duration of a chip operation. Moreover, since the plurality of memory sub-planes are verified at the same time, the area of the peripheral circuit may be reduced and the utilization rate may be increased, making the adaptability in size between the peripheral circuit and the memory cell array higher, thereby reducing the production cost.

### BRIEF DESCRIPTION OF THE DRAWINGS

In the drawings, unless otherwise specified, the same reference number throughout a plurality of drawings denotes identical or similar components or elements. These drawings are not necessarily drawn to scale. It is to be understood that these drawings merely describe some implementations disclosed according to examples of the present disclosure, and should not be construed as limiting the scope of the present disclosure.

FIG. 1 is a schematic diagram illustrating an electronic device according to examples of the present disclosure.

FIG. 2A is a schematic diagram illustrating a memory card according to examples of the present disclosure.

FIG. 2B is a schematic diagram illustrating a solid state drive according to examples of the present disclosure.

FIG. 3 is a schematic block diagram illustrating a three-dimensional NAND memory device according to examples of the present disclosure.

FIG. 4 is a schematic cross-sectional view illustrating a memory device according to examples of the present disclosure.

FIG. 5 is a schematic diagram illustrating a memory device comprising a memory cell array and a peripheral circuit according to examples of the present disclosure.

FIG. 6 is a schematic diagram illustrating a threshold voltage distribution of memory cells according to examples of the present disclosure.

FIG. 7 is a schematic diagram illustrating a memory plane according to examples of the present disclosure.

FIG. 8 is a schematic diagram illustrating a VFC circuit and a page buffer according to examples of the present disclosure.

FIG. 9 is a schematic diagram illustrating a memory device according to examples of the present disclosure.

FIG. 10 is a schematic diagram illustrating a verify counting circuit and a page buffer array according to examples of the present disclosure.

FIG. 11 is a diagram illustrating a timing of performing a verify operation according to examples of the present disclosure.

FIG. 12 is a schematic diagram illustrating current flow in the page buffer when a memory sub-plane does not pass verification according to examples of the present disclosure.

FIG. 13 is a schematic diagram illustrating current flow in the page buffer when a memory sub-plane passes verification according to examples of the present disclosure.

FIG. 14 is another schematic diagram illustrating the verify counting circuit and the page buffer array according to examples of the present disclosure.

FIG. 15 is a flow diagram illustrating an operation method of a memory device according to examples of the present disclosure.

### DETAILED DESCRIPTION

For ease of understanding the present disclosure, example implementations of the present disclosure will be described below in more details with reference to the relevant drawings. Although the example implementations of the present disclosure are shown in the drawings, it is to be understood that the present disclosure may be implemented in various forms and should not be limited by the example implementations set forth herein. Rather, these implementations are provided for a more thorough understanding of the present disclosure, and to fully convey a scope disclosed by the present disclosure to those skilled in the art.

In the following description, numerous example details are given in order to provide the more thorough understanding of the present disclosure. However, it is obvious to a person skilled in the art that the present disclosure may be implemented without one or more of these details. In some examples, in order to avoid confusing with the present disclosure, some technical features well-known in the field are not described. That is, not all the features of the actual examples are described herein, and well-known functions and structures are not described in detail.

In general, terms may be understood at least in part from usage in the context. For example, the term “one or more” as used herein, depending at least in part upon the context, can be used to describe any feature, structure, or characteristic in a singular sense or can be used to describe combinations of features, structures, or characteristics in a plural sense. Similarly, terms, such as “a/an” or “the”, likewise may be understood as conveying a singular use or a plural use, depending at least in part upon the context. In addition, the term “based on” may be understood as being not necessarily intended to convey an exclusive set of factors and may, instead, allow for the existence of additional factors not necessarily described expressly, likewise depending at least in part upon the context.

The terms used herein are only intended to describe the examples, and are not used as limitations on the present disclosure, unless otherwise defined. As used herein, unless otherwise indicated expressly in the context, “a”, “an” and “the” in a singular form are also intended to comprise a plural form. It is also to be understood that terms such as “composed of” and/or “comprise”, when used in this specification, determine the presence of described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to understand the present disclosure thoroughly, detailed operations and detailed structures will be proposed in the following description to set forth the technical solution of the present disclosure. Detailed descriptions of examples of the present disclosure are as follows. However, the present disclosure may also have other implementations in addition to these detailed descriptions.

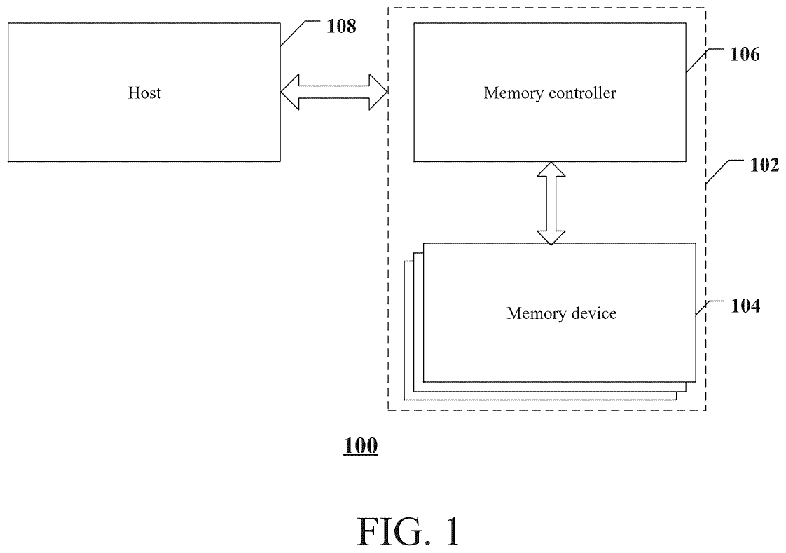

FIG. 1 is a schematic diagram illustrating an electronic device 100 according to examples of the present disclosure. The electronic device 100 may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic devices having memory devices therein. With reference to FIG. 1, the electronic device 100 may comprise a host 108 and a memory system 102, wherein the memory system 102 has one or more memory devices 104 and a memory controller 106. The host 108 may be a processor of the electronic device (such as a Central Processing Unit (CPU), or a System on Chip (SoC) (such as an Application Processor (AP)). The host 108 may be configured to send or receive data to or from the memory device 104.

According to some implementations, the memory controller 106 is coupled to the memory device 104 and the host 108, and configured to control the memory device 104. The memory controller 106 can manage data stored in the memory device 104 and communicate with the host 108. In some implementations, the memory controller 106 is designed for operating in a low duty-cycle environment, such as a Secure Digital (SD) card, a Compact Flash (CF) card, a Universal Serial Bus (USB) flash drive, or other media for use in electronic devices such as a personal computer, a digital camera, a mobile phone, etc. In some implementations, the memory controller 106 is designed for operating in a high duty-cycle environment, such as a Solid State Disk (SSD) or an embedded Multi-Media Card (eMMC) used as a data memory for mobile devices, such as a smartphone, a tablet computer, a laptop computer, etc., and an enterprise memory array.

The memory controller 106 may be configured to control operations of the memory device 104, such as read, erase, and program operations. The memory controller 106 may be further configured to manage various functions with respect to data stored or to be stored in the memory device 104, including, but not limited to, bad-block management, garbage collection, logical-to-physical address translation, wear leveling, etc. In some implementations, the memory controller 106 is further configured to process Error Correction Code (ECC) with respect to the data read from or written to the memory device 104. The memory controller 106 may also perform any other suitable functions, e.g., formatting the memory device 104. The memory controller 106 may communicate with an external device (e.g., the host 108 in FIG. 1) according to a particular communication protocol. For example, the memory controller 106 may communicate with an external device through at least one of various interface protocols, such as a USB protocol, an MMC protocol, a Peripheral Component Interconnect (PCI) protocol, a Peripheral Component Interconnect Express (PCI-E) protocol, an Advanced Technology Attachment (ATA) protocol, a serial-ATA protocol, a parallel-ATA protocol, a Small Computer System Interface (SCSI) protocol, an Enhanced Small Disk Interface (ESDI) protocol, an Integrated Drive Electronics (IDE) protocol, a Firewire protocol, etc.

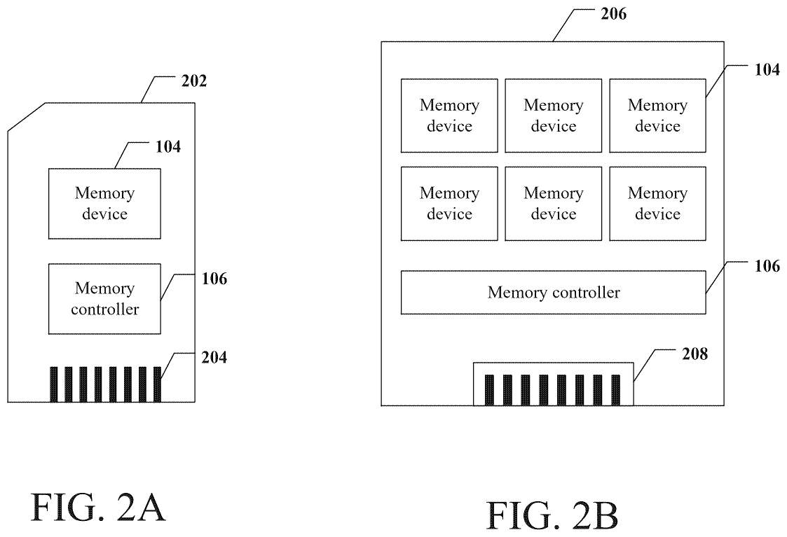

The memory controller 106 and the one or more memory devices 104 may be integrated into various types of memory devices, for example, be comprised in the same package (such as a Universal Flash Storage (UFS) package or an eMMC package). That is, the memory system 102 can be implemented and packaged to different types of end electronic products. In an example as shown in FIG. 2A, the memory controller 106 and a single memory device 104 may be integrated into a memory card 202. The memory card 202 may comprise a Personal Computer Memory Card (PC card), a CF card, a Smart Media (SM) card, a memory stick, a Multi-Media Card (MMC, Reduced-Size MMC (RS-MMC), MMCmicro), an SD card (SD, miniSD, microSD, Reduced-Size MMC (SDHC)), and a UFS, etc. The memory card 202 may further comprise a memory card connector 204 coupling the memory card 202 with a host (e.g., the host 108 in FIG. 1). In another example as shown in FIG. 2B, the memory controller 106 and the plurality of memory devices 104 may be integrated into an SSD 206. The SSD 206 may further comprise an SSD connector 208 coupling the SSD 206 with a host (e.g., the host 108 in FIG. 1). In some implementations, the storage capacity and/or operation speed of the SSD 206 are greater than those of the memory card 202.

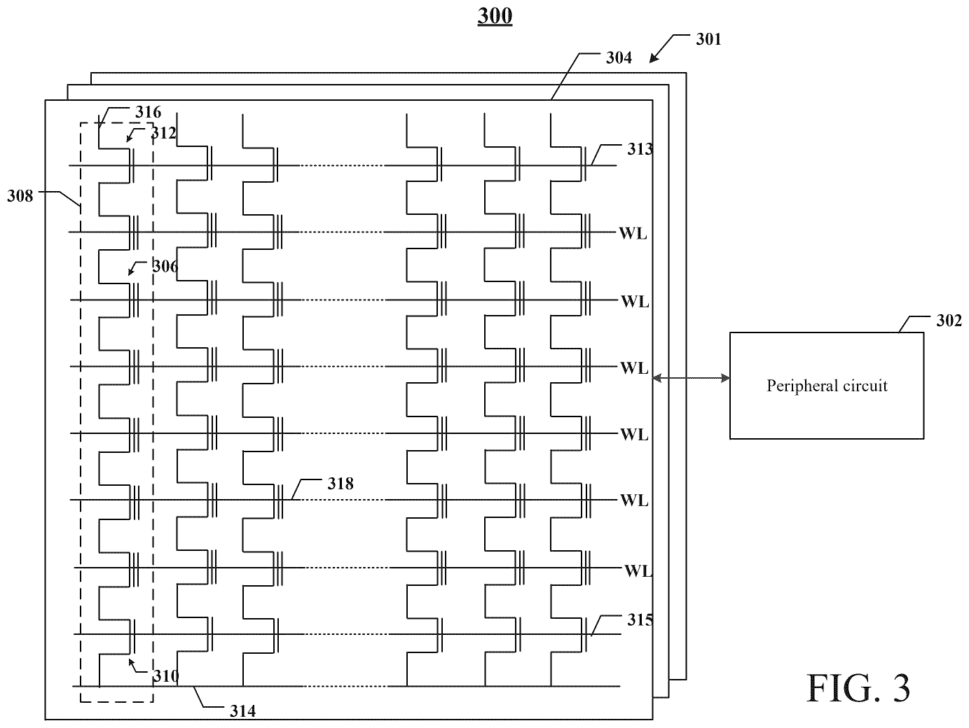

FIG. 3 is a schematic block diagram illustrating a three-dimensional NAND memory device 300 according to examples of the present disclosure. The memory device 300 may be an example of the memory device 104 in FIG. 1. The memory device 300 may comprise a memory cell array 301 and a peripheral circuit 302 coupled to the memory cell array 301. The memory cell array 301 as being a three-dimensional NAND memory cell array is illustrated as an example, wherein memory cells 306 are provided in an array of NAND memory strings 308, and each NAND memory string 308 extends vertically above a substrate (not shown). In some implementations, each NAND memory string 308 may comprise a plurality of memory cells 306 coupled in series and stacked vertically. Each memory cell 306 may maintain a continuous analog value, such as voltage or charge, which depends on the number of electrons trapped in a region of the memory cell 306. Each memory cell 306 may be a floating gate type memory cell that comprises a floating gate transistor, or a charge trap type memory cell that comprises a charge trap transistor.

In some implementations, each memory cell 306 is a Single Level Cell (SLC) that has two possible memory states and thus may store one bit of data. For example, a first memory state “0” may correspond to a first voltage range, and a second memory state “1” may correspond to a second voltage range. In some implementations, each memory cell 306 is a Multi Level Cell (MLC) that can store more than one bit of data in more than four memory states. For example, the MLC may store two bits per cell, three bits per cell (also referred to as a Triple Level Cell (TLC)), or four bits per cell (also referred to as a Quad Level Cell (QLC)). Each MLC can be programmed to take a range of possible nominal storage values. In an example, if each MLC stores two bits of data, the MLC may be programmed to write one of three possible nominal storage values to the cell, while a fourth nominal storage value may be used to represent an erase state.

As shown in FIG. 3, each NAND memory string 308 may comprise a Bottom Select Gate (BSG) 310 at its source terminal and a Top Select Gate (TSG) 312 at its drain terminal. The BSG 310 and the TSG 312 may be configured to activate a selected NAND memory string 308 during read and program operations. In some implementations, sources of the NAND memory strings 308 in the same memory block 304 are coupled through the same Source Line (SL) 314 (such as a common SL). In other words, according to some implementations, all the NAND memory strings 308 in the same memory block 304 have an Array Common Source (ACS). According to some implementations, the TSG 312 of each NAND memory string 308 is coupled to a respective Bit Line (BL) 316 which data can be read from or written to via an output bus (not shown). In some implementations, each NAND memory string 308 is configured to be selected or unselected by applying a select voltage (e.g., above a threshold voltage of a transistor having the TSG 312) or an unselect voltage (such as 0 V) to the respective TSG 312 via one or more TSG lines 313 and/or by applying a select voltage (e.g., above a threshold voltage of a transistor having the BSG 310) or an unselect voltage (such as 0 V) to the respective BSG 310 via one or more BSG lines 315.

As shown in FIG. 3, the NAND memory strings 308 may be organized into a plurality of memory blocks 304, and each of the memory blocks 304 may have a common source line 314 (e.g., coupled to the ground). In some implementations, each memory block 304 is a basic data unit for the erase operation, e.g., all the memory cells 306 on the same memory block 304 are erased at the same time. In order to erase the memory cells 306 in a selected memory block, the source line coupled to the selected memory block as well as an unselected memory block in the same plane as the selected memory block can be biased with an erase voltage (Vers) (such as a high positive voltage (e.g., 20 V or higher)). It is to be understood that, in some examples, an erase operation may be performed at a half memory block level, a quarter memory block level, or a level having any suitable number of memory blocks or any suitable fractions of a memory block. The memory cells 306 of adjacent ones of the NAND memory strings 308 may be coupled through word lines 318, and the word lines 318 select which row of memory cells 306 is affected by the read and program operations. In some implementations, the memory cells 306 in the memory block 304 that are coupled to the same word line 318 may constitute at least one physical page. Each word line 318 may comprise a plurality of control gates (gate electrodes) at each memory cell 306 in the respective physical page and a gate line coupling the control gates.

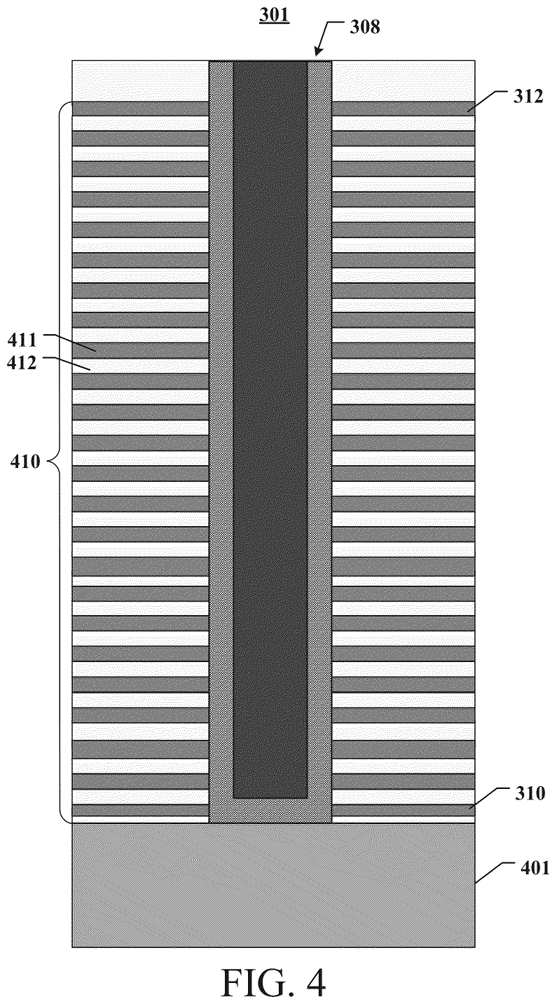

FIG. 4 is a schematic cross-sectional view illustrating a memory device according to examples of the present disclosure. With reference to FIG. 4, the NAND memory string 308 may comprise a stack structure 410 which comprises a plurality of gate layers 411 and a plurality of insulation layers 412 that are disposed as being stacked sequentially and alternately, and the memory string 308 penetrating through the gate layers 411 and the insulation layers 412 vertically. The gate layers 411 and the insulation layers 412 may be stacked alternately, and two adjacent ones of the gate layers 411 are spaced apart by one insulation layer 412. The number of pairs of the gate layers 411 and the insulation layers 412 in the stack structure 410 may determine the number of memory cells that are comprised in the memory cell array 301.

A composition material of the gate layers 411 may comprise a conductive material. The conductive material includes, but is not limited to, tungsten (W), cobalt (Co), copper (Cu), aluminum (Al), polysilicon, doped silicon, silicide, or any combination thereof. In some implementations, each gate layer 411 comprises a metal layer, e.g., a tungsten layer. In some implementations, each gate layer 411 comprises a doped polysilicon layer. Each gate layer 411 may comprise a control gate surrounding the memory cells. The gate layer 411 at the top of the stack structure 410 may extend laterally as a top select gate line; the gate layer 411 at the bottom of the stack structure 410 may extend laterally as a bottom select gate line; and the gate layer 411 extending laterally between the top select gate line and the bottom select gate line may serve as a word line layer.

In some examples, the stack structure 410 may be disposed on a substrate 401. The substrate 401 may comprise silicon (e.g., monocrystalline silicon), silicon germanium (SiGe), gallium arsenide (GaAs), germanium (Ge), silicon on insulator (SOI), germanium on insulator (GOI), or any other suitable materials.

In some examples, the NAND memory string 308 comprises a channel structure extending through the stack structure 410 vertically. In some implementations, the channel structure comprises a channel hole filled with (one or more) semiconductor materials (e.g., as a semiconductor channel) and (one or more) dielectric materials (e.g., as a memory film). In some implementations, the semiconductor channel comprises silicon, e.g., polysilicon. In some implementations, the memory film is a composite dielectric layer comprising a tunneling layer, a storage layer (also referred to as a “charge trap/storage layer”), and a barrier layer. The channel structure may have a cylindrical shape (such as a pillar shape). According to some implementations, the semiconductor channel, the tunneling layer, the storage layer, and the barrier layer are arranged radially from the center toward the outer surface of the pillar in this order. The tunneling layer may comprise silicon oxide, silicon oxynitride, or any combination thereof. The storage layer may comprise silicon nitride, silicon oxynitride, or any combination thereof. The barrier layer may comprise silicon oxide, silicon oxynitride, a high dielectric constant (high-k) dielectric, or any combination thereof. In an example, the memory film may comprise a composite layer of silicon oxide/silicon oxynitride/silicon oxide (ONO).

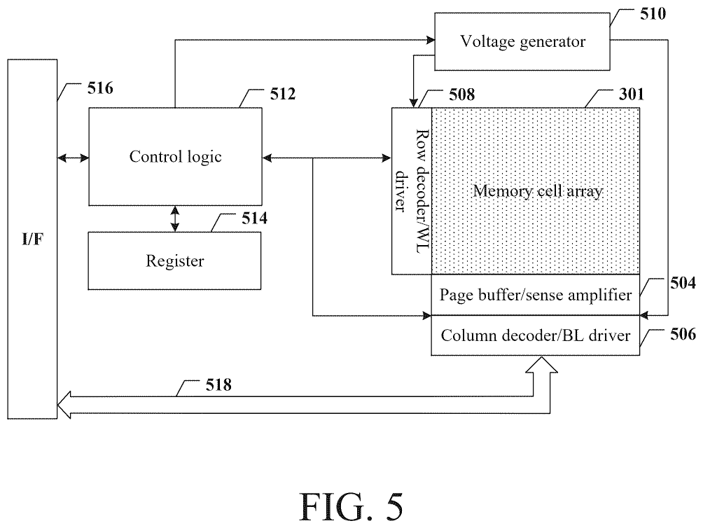

Referring back to FIG. 3, the peripheral circuit 302 may be coupled to the memory cell array 301 through the bit line 316, the word line 318, the source line 314, the BSG line 315 and the TSG line 313. The peripheral circuit 302 may comprise any suitable analog, digital, and hybrid signal circuits for facilitating operations of the memory cell array 301 by applying voltage signals and/or current signals to each target memory cell 306 and sensing voltage signals and/or current signals from each target memory cell 306 through the bit line 316, the word line 318, the source line 314, the BSG line 315, and the TSG line 313. The peripheral circuit 302 may comprise various types of peripheral circuits formed using the metal-oxide-semiconductor (MOS) technology. For example, FIG. 5 shows some example peripheral circuits. The peripheral circuit 302 comprises a page buffer/sense amplifier 504, a column decoder/bit line driver 506, a row decoder/word line driver 508, a voltage generator 510, a control logic 512, a register 514, an interface 516, and a data bus 518. It is to be understood that, in some examples, an additional peripheral circuit not shown in FIG. 5 may also be comprised.

The page buffer/sense amplifier 504 may be configured to read and program (write) data from and to the memory cell array 301 according to control signals from the control logic 512. In an example, the page buffer/sense amplifier 504 may store one page of program data (write data) to be programmed into one physical page of the memory cell array 301. In another example, the page buffer/sense amplifier 504 may perform a program verify operation to ensure that data has been properly programmed into the memory cells 306 coupled to the selected word line 318. In still another example, the page buffer/sense amplifier 504 may also sense low power signals from the bit line 316 that represent data bits stored in the memory cells 306, and amplify a small voltage swing to a recognizable logic level during the read operation. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512, select/unselect the memory block 304 of the memory cell array 301, and select/unselect the word line 318 of the memory block 304. The row decoder/word line driver 508 may be further configured to drive the word line 318 using a word line voltage generated from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 coupled to (one or more) selected word lines 318. The voltage generator 510 may be configured to be controlled by the control logic 512 and generate the word line voltage (such as a read voltage, a program voltage, a pass voltage, a channel boost voltage, a verify voltage, etc.), the bit line voltage, and a source line voltage to be supplied to the memory cell array 301.

The control logic 512 may be coupled to each peripheral circuit as described above and configured to control operations of each peripheral circuit. The register 514 may be coupled to the control logic 512 and comprise a state register, a command register, and an address register for storing state information, command operation code (OP code), and a command address for controlling the operations of each peripheral circuit. The interface 516 may be coupled to the control logic 512, and act as a control buffer to buffer and relay control commands received from a host (not shown) to the control logic 512 and buffer and relay state information received from the control logic 512 to the host. The interface 516 may also be coupled to the column decoder/bit line driver 506 via the data bus 518 and act as a data I/O interface and a data buffer to buffer and relay the data to and from the memory cell array 301.

In a NAND chip, programming and erasing of memory cells are required, and whether the programming or the erasing succeeds may be judged by verifying the number of fail bits in the programming or erasing, wherein a respective circuit performing VFC is referred to as a VFC circuit. Therefore, the VFC circuit is very important and essential for the NAND chip.

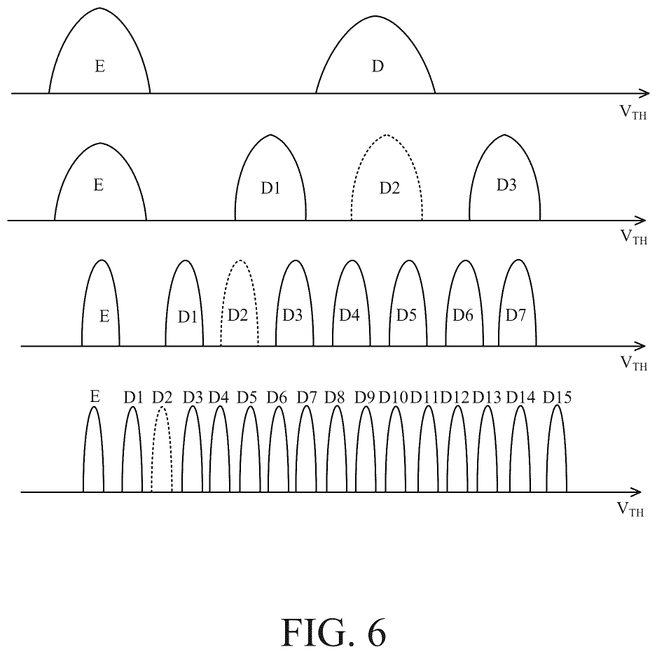

FIG. 6 is a schematic diagram illustrating a threshold voltage distribution of memory cells according to examples of the present disclosure. A memory cell may be configured to store one or more bits of logical page data, and accordingly, the memory cell may be a single level cell SLC, a multi level cell MLC, a triple level cell TLC, or a quad level cell QLC, etc. As shown in FIG. 6, the single level cell SLC corresponds to two threshold voltage distributions E and D; the multi level cell MLC corresponds to four threshold voltage distributions E, D1, D2, and D3; the triple level cell TLC corresponds to eight threshold voltage distributions E, D1, D2, D3, D4, D5, D6, and D7; and the quad level cell QLC corresponds to sixteen threshold voltage distributions E, D1, D2, D3, D4, D5, D6, D7, D8, D9, D10, D11, D12, D13, D14, and D15, wherein the threshold voltage distribution E denotes an erase state, and the threshold voltage distributions D to D15 denote different program states respectively.

During each round of program verification for the MLC, TLC, or QLC, one of the plurality of program states may be selected to perform the program verification, wherein the number of memory cells required to be subjected to VFC is 16 KB/2ⁿ bits, and n is the number of bits of logical page data stored in the memory cell. For example, for verification of D2 in the MLC, the number of memory cells required to be subjected to VFC is 16 KB/4 bits; for verification of D2 in TLC, the number of memory cells required to be subjected to VFC is 16 KB/8 bits; and for verification of D2 in QLC, the number of memory cells required to be subjected to VFC is 16 KB/16 bits. If the number of fail bits in a plurality of verified memory cells is greater than a preset value, a program pulse continues to be applied to the plurality of verified memory cells, until the memory cells are programmed to D2; and if the number of fail bits in the plurality of verified memory cells is less than or equal to the preset value, the plurality of memory cells have been programmed to D2, and a program inhibit pulse is applied to the plurality of memory cells. Here, the preset value may be 50, 100, or other values.

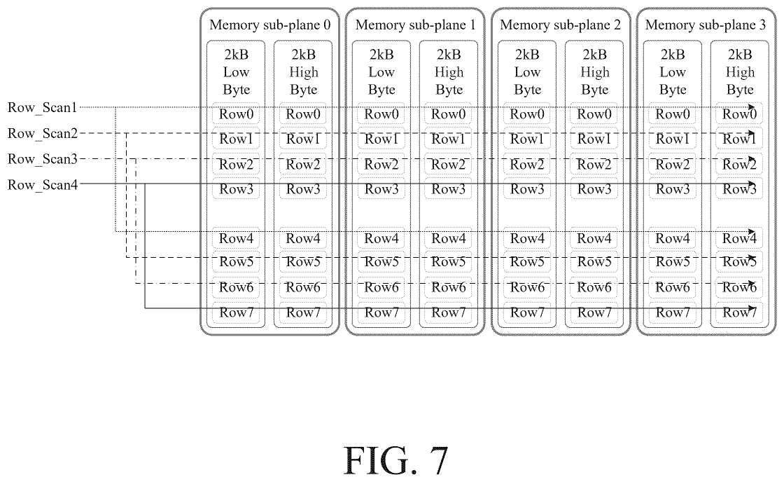

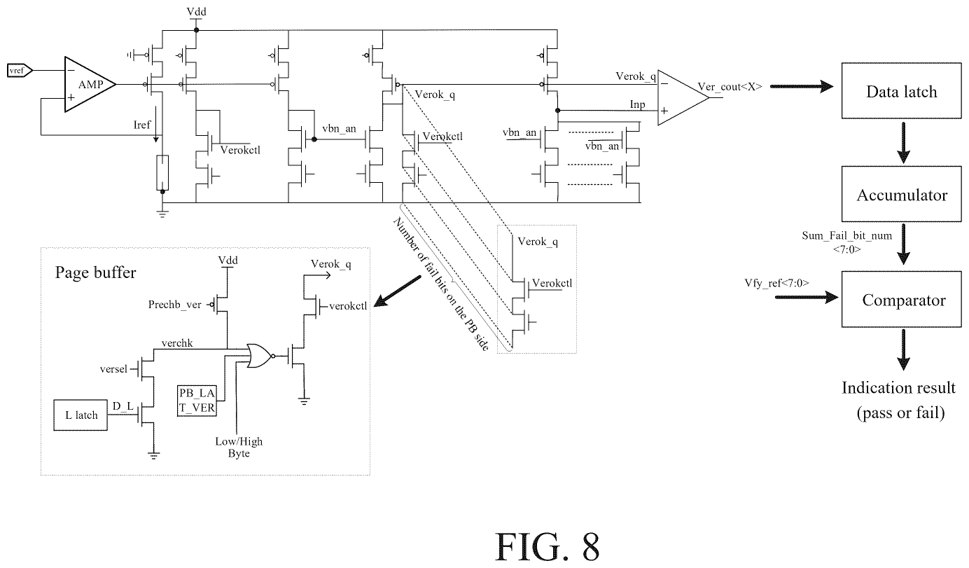

FIG. 7 is a schematic diagram illustrating a memory plane according to examples of the present disclosure. A memory cell array may be divided into a plurality of memory planes, and each memory plane may be divided into a plurality of memory sub-planes. As shown in FIG. 7, the memory plane may be divided into memory sub-planes 0 to 3, wherein each memory sub-plane is a quarter of the memory plane. The memory sub-plane may comprise 8 rows of memory cells, and the 8 rows of memory cells are Row0 to Row7, respectively. Row0 and Row4 of each memory sub-plane are coupled with a row scanning circuit Row_Scan1, Row1 and Row5 of each memory sub-plane are coupled with a row scanning circuit Row_Scan2, Row2 and Row6 of each memory sub-plane are coupled with a row scanning circuit Row_Scan3, and Row3 and Row7 of each memory sub-plane are coupled with a row scanning circuit Row_Scan4. During execution of VFC, the VFC may be executed row by row by driving respective row scanning circuits. Example description will be performed below in conjunction with a circuit shown in FIG. 8.

FIG. 8 is a schematic diagram illustrating the VFC circuit and the page buffer according to examples of the present disclosure. Taking the verification of D2 as an example, the control logic 512 in FIG. 5 selects the row scanning circuit Row_Scan1 to perform VFC on a plurality of memory cells in Row0 and Row4. The page buffer senses a fail bit current through the bit line and latches fail bit information through an L latch, and the fail bit information may be transmitted to the VFC circuit via a versel circuit in FIG. 8. The VFC circuit generates an error bit signal V_{erok_q} based on the fail bit information, and generates a plurality of reference signals Inp based on a received input signal V_{ref}. The error bit signal V_{erok_q} is compared with the plurality of reference signals Inp sequentially, to obtain a verify result V_{er_cout<X>}, wherein V_{er_cout<X>} may be latched in a data latch.

By analogy, the row scanning circuits Row_Scan2, Row_Scan3, and Row_Scan4 are selected row by row, so that a verify result for each row of memory cells may be obtained. An accumulator accumulates verify results for all the rows of memory cells, to obtain a sum Sum_Fail_bit_num<7:0> of the numbers of fail bits of the memory plane. A comparator compares the sum Sum_Fail_bit_num<7:0> of the numbers of fail bits and the preset value Vfy_ref<7:0>, to output an indication results. Based on the indication result, the control logic determines whether the programming of the memory plane passes or fails.

It is to be noted that one memory sub-plane in FIG. 7 is coupled with one page buffer through the bit line. Accordingly, during the execution of the VFC, a plurality of PBs on the PB side (referring to FIG. 8) are required to perform a plurality of times of scanning, resulting in a very long VFC execution duration of the VFC circuit. The VFC execution duration of the VFC circuit will directly affect an overall duration of the chip. With the iteration of NAND chips, requirements of specification of the chips become increasingly high, wherein an operation duration of the chip is one of the requirements, and the long VFC execution duration will lower the possibility of reducing a program duration or an erase duration. Therefore, reducing the VFC execution duration becomes increasingly important.

In addition, the utilization rate of the peripheral circuit becomes particularly important with the increase in a capacity of the memory cell array and the continuous optimization of the process, wherein an implementation of the VFC circuit as being an analog circuit requires the use of numerous MOS transistors, making the VFC circuit occupy a large area, which is not favorable to the increase of the utilization rate of the peripheral circuit. For the three-dimensional NAND chip in which the peripheral circuit is bonded with the memory cell array, the VFC circuit occupies a large area, reducing the adaptability in size between the peripheral circuit and the memory cell array, thereby increasing the production cost.

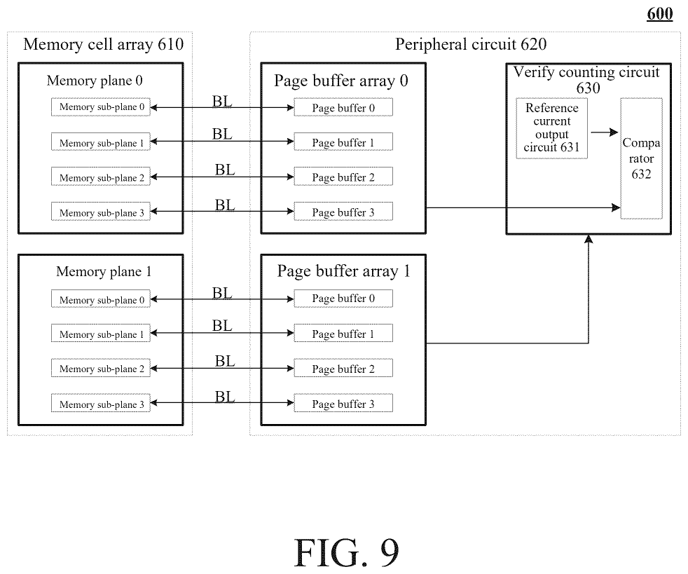

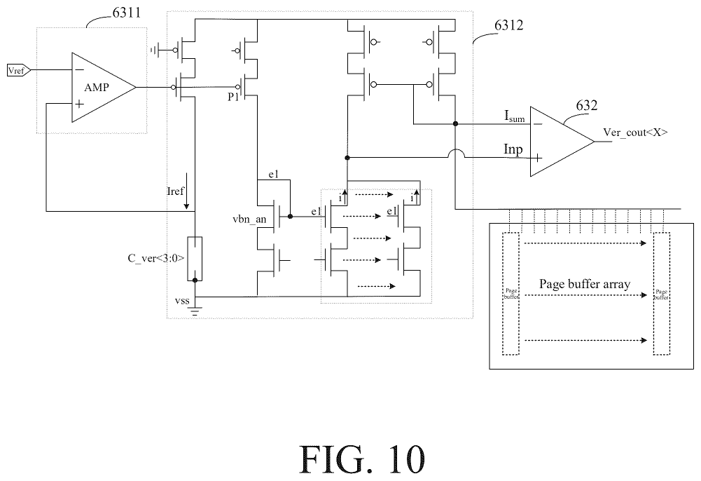

Based on one or more of the above technical problems, examples of the present disclosure provide a memory device. FIG. 9 is a schematic diagram illustrating a memory device according to examples of the present disclosure. FIG. 10 is a schematic diagram illustrating a verify counting circuit and a page buffer array according to examples of the present disclosure. Example description of the memory device, the page buffer array, and the verify counting circuit provided in the examples of the present disclosure will be performed below in conjunction with FIG. 9 and FIG. 10.

With reference to FIG. 9, the memory device 600 comprises a memory cell array 610 and a peripheral circuit 620. The memory cell array 610 comprises a memory plane comprising a plurality of memory sub-planes. The peripheral circuit 620 is coupled with the memory cell array 610 and configured to: perform verify operations on the plurality of memory sub-planes at the same time, to obtain a verify result for the memory plane; and determine the number of fail bits of the memory plane based on the verify result. For ease of understanding, in examples below, the memory cell array 610 comprising a memory plane 0 and a memory plane 1, with each memory plane comprising a memory sub-plane 0, a memory sub-plane 1, a memory sub-plane 2, and a memory sub-plane 3 is illustrated as an example. There may be one or more memory planes in the memory cell array 610, the number of memory sub-planes in each memory plane is not limited to 4 as shown in FIG. 9, and the numbers of memory sub-planes in any two memory planes may be the same or different. The present disclosure does not impose any particular limitations thereon.

In an example, the peripheral circuit 620 comprises a control logic which controls a verify operation to be performed on the memory sub-plane 0, the memory sub-plane 1, the memory sub-plane 2, and the memory sub-plane 3 of the memory plane 0 at the same time, so as to obtain a verify result for the memory plane 0. Since the 4 memory sub-planes are verified at the same time, a fail bit count of the memory plane 0 may be obtained through one time of scanning, thereby reducing the VFC execution duration, which is favorable to the reduction of the operation duration of the chip. Moreover, since the 4 memory sub-planes are verified at the same time, the 4 line scanning circuits in FIG. 7 may be omitted, reducing the number of line scanning circuits, which is favorable to the reduction of the area of the peripheral circuit 620 and the increase of the utilization rate, making the adaptability in size between the peripheral circuit 620 and the memory cell array 610 higher, thereby reducing the production cost. It is to be noted that the control logic described in the examples of the present disclosure may comprise a plurality of functional modules. Each functional module of the control logic may be a software module running on a processor that is part of the control logic, or may be a hardware module, or may be a combination of a software module and a hardware module. Of course, in other examples, the control logic may also control a verify operation to be performed on the memory sub-plane 0, the memory sub-plane 1, the memory sub-plane 2, and the memory sub-plane 3 of the memory plane 1 at the same time, so as to obtain a verify result for the memory plane 1.

In some examples, the operation method further comprises: selecting at least one memory plane from a plurality of memory planes, and perform the verify operation on the selected memory plane. Here, before a verify operation is performed, at least one memory plane may be selected from the memory plane 0 and the memory plane 1 to perform the verify operation. The verify operation comprises a program verify operation or an erase verify operation. It is to be understood that performing a program verify operation on the plurality of memory sub-planes of the memory plane at the same time is favorable to the reduction of a program duration, and performing an erase verify operation on the plurality of memory sub-planes of the memory plane at the same time is favorable to the reduction of an erase duration.

In some examples, the peripheral circuit 620 comprises a page buffer array and a verify counting circuit 630. The page buffer array comprises a plurality of page buffers, wherein one of the plurality of page buffers is coupled with one of the plurality of memory sub-planes through a bit line, and each page buffer is configured to sense a fail bit current of the coupled memory sub-plane through the bit line. The verify counting circuit 630 is coupled with the page buffer array and configured to: obtain the verify result based on a sum of fail bit currents of the plurality of memory sub-planes; and determine the number of fail bits of the memory plane based on the verify result.

With reference to FIG. 9, the page buffer array 0 comprises a page buffer 0, a page buffer 1, a page buffer 2, and a page buffer 3. During the verify operation, the page buffer 0 may sense a fail bit current I₀ of the memory sub-plane 0 through the bit line, the page buffer 1 may sense a fail bit current I₁ of the memory sub-plane 1 through the bit line, the page buffer 2 may sense a fail bit current I₂ of the memory sub-plane 2 through the bit line, and the page buffer 3 may sense a fail bit current I₃ of the memory sub-plane 3 through the bit line. It is to be noted that the plurality of page buffers in the page buffer array may be connected in parallel, as shown in FIG. 10, so as to obtain the sum Iₛᵤₘ of the fail bit currents. In this example, Iₛᵤₘ=I₀+I₁+I₂+I₃.

The plurality of page buffers output the fail bit currents to the verify counting circuit 630. In an example, if the memory sub-plane passes the program verification, there is no current on a corresponding data path; and if the memory sub-plane does not pass the program verification, the page buffer corresponding to memory sub-plane outputs the corresponding fail bit current. The fail bit currents output by the plurality of page buffers are accumulated as the verify result obtained by performing the program verification on the memory plane. The number of fail bits of the memory plane may be determined by means of the verify result. It is to be noted that the control logic may control the plurality of page buffers of the page buffer array to sense the fail bit currents of the corresponding memory sub-planes at the same time. As such, an execution duration of the fail bit count may be reduced, which is favorable to the reduction of the operation duration of the chip.

In some examples, with reference to FIG. 9, the verify counting circuit 630 comprises a reference current output circuit 631 and a comparator 632. The reference current output circuit 631 is configured to output at least one reference current. A first input end of the comparator 632 is coupled with the page buffer array, and a second input end of the comparator 632 is coupled with the reference current output circuit 631. The comparator 632 is configured to: compare the at least one reference current and the sum of the fail bit currents, and output the verify result.

The reference current output circuit 631 may receive an input signal, such as a clock signal, an enable signal, or a voltage-current signal, to cause the verify counting circuit 630 to enable a fail bit count. In a specific example, the reference current output circuit 631 may also output the at least one reference current based on the input signal.

In an example, with reference to FIG. 10, the reference current output circuit 631 comprises a comparison circuit 6311 and a reference current generation circuit 6312. An input end of the comparison circuit 6311 is used to receive an input signal V_{ref} and output an enable signal according to its magnitude, wherein the enable signal is used to turn on some of transistors in the reference current generation circuit 6312, so as to enable the reference current generation circuit 6312. An output end of the comparison circuit 6311 is coupled with a transistor P1. When the comparison circuit 6311 outputs a low level, the transistor P1 is on, and a control signal e1 is generated, wherein the control signal e1 is used to enable the reference current generation circuit 6312 to generate at least one reference current Inp. The comparator 632 may determine a range of magnitude of the sum Iₛᵤₘ of the fail bit currents by comparing the at least one reference current Inp and the sum Iₛᵤₘ of the fail bit currents, wherein the range may reflect the number of fail bits of the memory plane, thereby determining the fail bit count using the verify result.

It is to be noted that, in the examples of the present disclosure, the comparator 632 is a circuit element that is coupled with the reference current output circuit 631 and the page buffer array and compares current signals (the reference current Inp and the sum Iₛᵤₘ of the fail bit currents) to determine whether the two current signals are equal or a relationship of magnitude therebetween. An analog signal is input to two input ends of the comparator 632, to output a binary signal “0” or “1” (denoted by a low level or a high level). In some examples, when a specific number of fail bits is required to be calculated according to the binary signal, a comparison result of the comparator 632 may be denoted by a symbol Ver_cout<X>. In an example, if the sum Iₛᵤₘ of the fail bit currents is greater than the reference current Inp, Ver_cout<X>=1 is output; and if the sum Iₛᵤₘ of the fail bit currents is less than the reference current Inp, Ver_cout<X>=0 is output. It is to be noted that the number of the reference currents Inp is required to be determined according to an actual situation.

In an example, with reference to FIG. 10, the reference current generation circuit 6312 comprises a plurality of branches connected in parallel and used to generate the at least one reference current. As shown in FIG. 10, each branch can provide a current i when being on, and a total current obtained by the plurality of branches connected in parallel is the reference current Inp. It may be understood that different reference currents may be output by varying the number of on branches. In an example, the more on branches in the plurality of branches, the larger the output reference current; the less on branches in the plurality of branches, the smaller the output reference current.

In an example, the sum Iₛᵤₘ of the fail bit currents and a first reference current Inp1 may be compared first, if the comparator 632 outputs a result “1”, it indicates that the sum Iₛᵤₘ of the fail bit currents is greater than the reference current Inp1, and then the sum Iₛᵤₘ of the fail bit currents and a second reference current Inp2 (Inp2>Inp1) are compared, . . . , until the comparator 632 outputs a result “0”, whereby the range of magnitude of the sum Iₛᵤₘ of the fail bit currents may be determined, thereby obtaining the verify result. It may be understood that the examples of the present disclosure allow the multiplexing of different reference currents with the comparator 632, thereby reducing the area of the verify counting circuit 630, which is favorable to the increase of the utilization rate of the peripheral circuit 620.

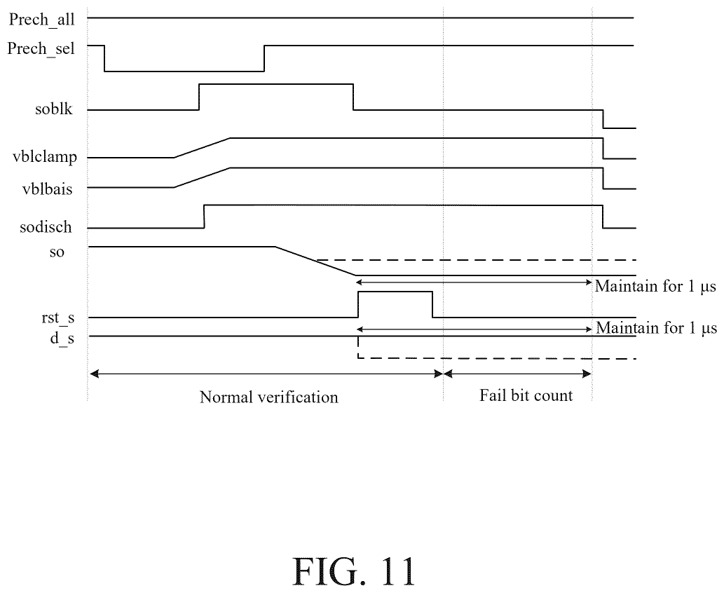

In some examples, each page buffer is further configured to maintain the sensed fail bit current for a preset time period. During the verify operation performed on the plurality of memory sub-planes at the same time, the fail bit current sensed by each page buffer may be maintained for the preset time period, so as to be capable of sensing the current on the bit lines coupled with each memory sub-plane. In an example, as shown in FIG. 11, a control signal applied to a circuit element of the page buffer may be maintained for 1 microsecond (μs), and during the maintaining of 1 μs, the verify counting circuit 630 performs the fail bit count. Here, the preset time period may be determined according to the actual number of memory sub-planes and a circuit design, and is not limited to 1 us. The solution of counting by scanning row by row in FIG. 7 and FIG. 8 requires about 14 us, while the solution provided in the present disclosure requires only 1 us, saving about 13 us, e.g., reducing the VFC execution duration.

In some examples, the reference current output circuit 631 is particularly configured to output the reference current after the fail bit current has been maintained for the preset time period. It may be understood that, after the fail bit current has been maintained for the preset time period, each page buffer in the page buffer array senses the corresponding fail bit current. At this time, the output reference current is compared with the sum of the fail bit currents of the plurality of memory sub-planes, so that an increase in power consumption caused by excessively early output of the reference current may be avoided.

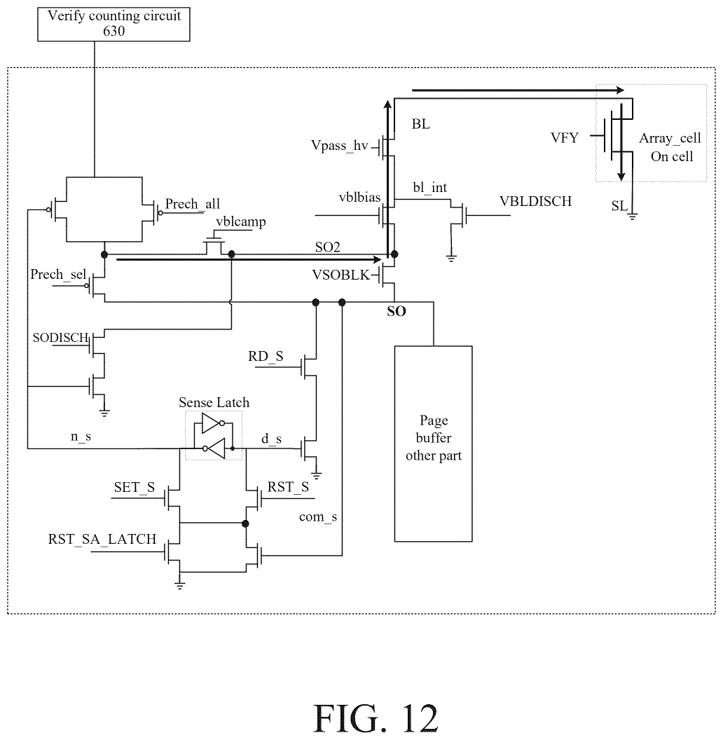

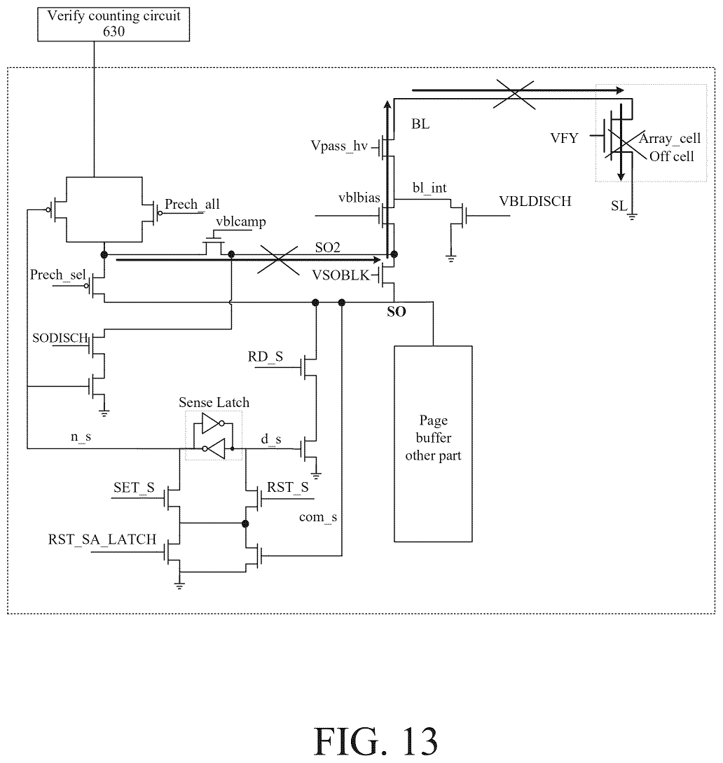

In some examples, the page buffer comprises: a precharge circuit, wherein a first end of the precharge circuit is coupled with the bit line through a sensing node, and a second end of the precharge circuit is coupled with the verify counting circuit 630. As shown in FIG. 12 or FIG. 13, the precharge circuit is an NMOS transistor, and a control terminal of the NMOS transistor receives a precharge signal Prech_all. Of course, in other examples, the precharge circuit may further comprise a combination of a PMOS transistor and other electronic elements. In a specific example, the second end of the precharge circuit of each page buffer in the page buffer array is coupled with the verify counting circuit 630.

It is to be pointed out that, typically, the second end of the precharge circuit is coupled with a supply end, wherein when the precharge signal Prech_all is at a high level, the NMOS transistor is on. The sensing node and the bit line may be charged to VDD via the precharge circuit before the program verification. A current on the bit line is sensed by means of bit line discharge during the program verification, and then converted by the L latch to obtain the fail bit current, for example, the L latch is required to perform VFC. Here, the fail bit current obtained by means of conversion via the L latch is typically at a microampere (μA) level, limiting the number in each time of scanning for counting, making it difficult to count more fail bits. For example, if the reference current is 100 μA and a corresponding fail bit current obtained by converting a memory cell current via the L latch is 10 μA, only 10 fail bits can be counted.

In the examples of the present disclosure, by coupling the second end of the precharge circuit with the verify counting circuit 630, the sensed memory cell current may be used directly as the fail bit current, without generating the fail bit current by other circuits, so that a VFC execution process may be simplified, thereby reducing the VFC execution duration. Furthermore, since the memory cell current is at a nanoampere (nA) level, more bits may be counted so that a plurality of memory sub-planes may be scanned in one time.

In an example, if a selected memory cell is on (e.g., does not pass the program verification), there is a current on a memory string where the memory cell is located, wherein the flow of the current is as shown in FIG. 12, and the current is about several hundreds of nanoamperes. Accordingly, more fail bits may be calculated based on the reference current (typically at the microampere level). For example, if the reference current is 100 μA and a fail bit current corresponding to one fail bit is 100 nA, 1000 fail bits may be counted. That is, the examples of the present disclosure take advantage of the small memory cell current by directly using it as the fail bit current, so that more fail bits may be counted effectively in a short period of time. Moreover, since the memory cell current is small, a smaller reference current may be used for comparison, which favorable to the reduction of power consumption. Values here are only examples and may be reasonably selected according to the circuit design in a practical application, and the present disclosure does not impose any particular limitations thereon. Of course, if the selected memory cell is off (e.g., passes the program verification), there is no current or a very little (negligible) current on the memory string where the memory cell is located, as shown in FIG. 13.

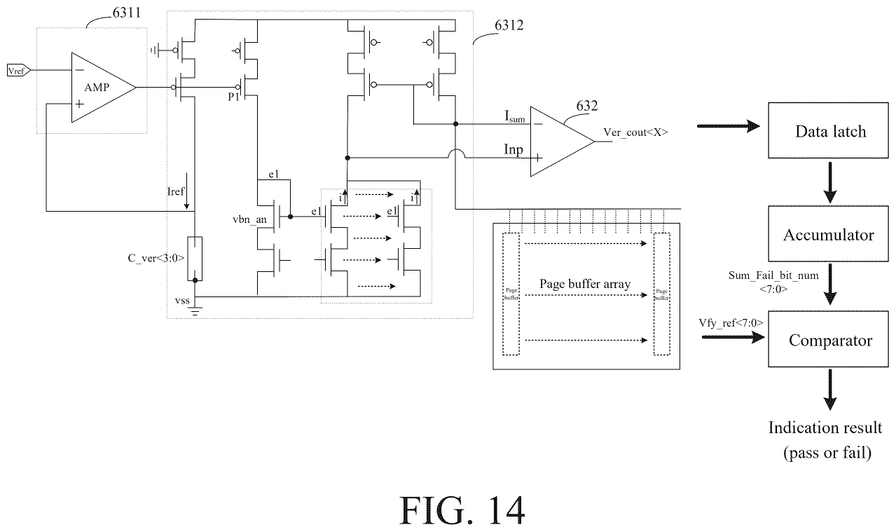

FIG. 14 is another schematic diagram illustrating the verify counting circuit 630 and the page buffer array according to examples of the present disclosure. With reference to FIG. 14, the verify counting circuit further comprises a data latch, an accumulator, other comparators, and etc. The data latch, accumulator, and other comparators may be referred to the relevant description in the example of FIG. 8, which is no longer repeated here.

Examples of the present disclosure provide a memory device comprising a memory cell array and a peripheral circuit, wherein the memory cell array comprises a memory plane, and the memory plane comprises a plurality of memory sub-planes; the peripheral circuit is coupled with the memory cell array and configured to: perform verify operations on the plurality of memory sub-planes at the same time, to obtain a verify result for the memory plane; and determine the number of fail bits of the memory plane based on the verify result. In a first aspect, the plurality of memory sub-planes are verified at the same time, and the fail bit count of the memory plane may be obtained through only one time of scanning, thereby reducing the VFC execution duration, which is favorable to the reduction of the operation duration of the chip. In a second aspect, the row scanning circuits and relevant circuits (such as the versel circuit, Prechb_ver circuit, etc., in FIG. 8) may be omitted, reducing the area of the page buffer, thus reducing the area of the peripheral circuit and increasing the utilization rate, making the adaptability in size between the peripheral circuit and the memory cell array higher, thereby reducing the production cost. In a third aspect, directly using the memory cell current as the fail bit current for counting allows more fail bits to be counted, and the reference current may also decrease as the fail bit current decreases, which is favorable to the reduction of power consumption. In a fourth aspect, directly coupling the second end of the precharge circuit to the verify counting circuit allows an implementation without complicated modifications. In a fifth aspect, since some circuits are omitted in the page buffer, a spare space may be provided, making a layout design of the chip more flexible, for example, wiring may be added to the saved space for use by other circuits, thereby providing more possibilities for signal wires of the chip. In a sixth aspect, the occurrence of a peak current may be avoided due to the small fail bit current.

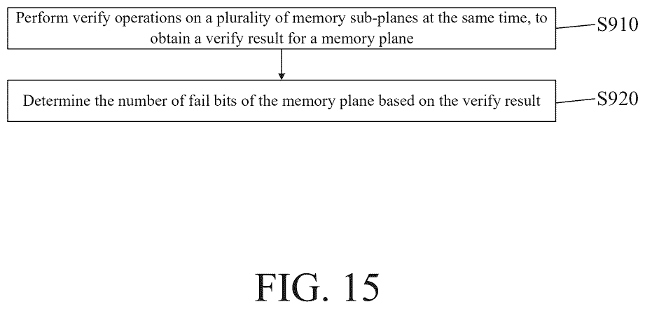

Based on the above-mentioned memory device, examples of the present disclosure provide an operation method of a memory device. FIG. 15 is a flow diagram illustrating an operation method of a memory device according to examples of the present disclosure. With reference to FIG. 15, the operation method at least comprises the following operations:

S910: performing verify operations on a plurality of memory sub-planes at the same time, to obtain a verify result for a memory plane; and

S920: determining the number of fail bits of the memory plane based on the verify result.

In some examples, the memory device further comprises a plurality of page buffers and a verify counting circuit, wherein one of the plurality of page buffers is coupled with one of the plurality of memory sub-planes through a bit line. S910 comprises: sensing, by each page buffer, a fail bit current of the coupled memory sub-plane through the bit line; and obtaining, by the verify counting circuit, the verify result based on a sum of fail bit currents of the plurality of memory sub-planes.

In some examples, S920 comprises: determining, by the verify counting circuit, the number of fail bits of the memory plane based on the verify result.

In some examples, the verify counting circuit comprises a reference current output circuit and a comparator, a first input end of the comparator is coupled with the plurality of page buffers, and a second input end of the comparator is coupled with the reference current output circuit; the obtaining, by the verify counting circuit, the verify result based on the sum of the fail bit currents of the plurality of memory sub-planes comprises: outputting, by the reference current output circuit, at least one reference current; and comparing, by the comparator, the at least one reference current and the sum of the fail bit currents, and outputting the verify result.

In some examples, the operation method further comprises: maintaining, by each page buffer, the sensed fail bit current for a preset time period.

In some examples, the outputting, by the reference current output circuit, the at least one reference current comprises: outputting, by the reference current output circuit, the reference current after the fail bit current has been maintained for the preset time period.

In some examples, the preset time period comprises 1 microsecond.

In some examples, the operation method further comprises: selecting at least one memory plane from a plurality of memory planes, and perform the verify operation on the selected memory plane.

In some examples, the verify operation comprises a program verify operation or an erase verify operation.

In the examples of the present disclosure, the operation method of the memory device may be performed by the control logic circuit in the memory device as described in any of the above examples, and the technical effects that can be realized by the memory device in the above examples all can be realized by this operation method of the memory device, which are no longer repeated one by one here. An example implementation of each operation of the operation method in the above examples is described in detail in relevant apparatus examples, which is no longer set forth in detail here.

Based on the above-mentioned memory device, examples of the present disclosure provide a memory system. The memory system comprises: one or more memory devices as described in any of the examples of the present disclosure; and a memory controller coupled to the memory device and configured to control the memory device.

The memory controller may be referred correspondingly to the memory controller 106 in the example shown in FIG. 1, and functions and applications of and interactive operations between the memory device and the memory controller are no longer repeated here.

Based on the memory system described above, examples of the present disclosure provide an electronic device, comprising the memory system described above.

The features disclosed in several apparatus examples provided by the present disclosure may be combined arbitrarily to obtain a new apparatus example in the case of no conflicts.

The methods disclosed in several method examples provided by the present disclosure may be combined freely to obtain new method examples in case of no conflicts.

It is to be understood that, references to “one example” or “an example” throughout this specification mean that particular features, structures, or characteristics related to the examples or example are included in at least one example of the present disclosure. Therefore, “in one example” or “in an example” presented everywhere throughout this specification does not necessarily refer to the same example. In addition, these specific features, structures or characteristics may be combined in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are used for description only, and do not represent advantages or disadvantages of the examples.

It is to be noted that, the term “include”, “comprise”, or any variants thereof herein is intended to cover non-exclusive inclusion, such that a process, a method, an article, or an apparatus comprising a series of elements comprise not only those elements, but also other elements not listed explicitly, or elements inherent to this process, method, article, or apparatus. Without further limitation, an element defined by a phrase “comprising one” do not preclude the presence of another identical element in the process, method, article or apparatus comprising this element.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory device, comprising:
a memory cell array comprising a memory plane, wherein the memory plane comprises a plurality of memory sub-planes; and
a peripheral circuit coupled with the memory cell array and configured to:
perform verify operations on the plurality of memory sub-planes at the same time to obtain a verify result of the memory plane; and
determine a number of fail bits of the memory plane based on the verify result.

2. The memory device of claim 1, wherein the peripheral circuit comprises:
a page buffer array comprising a plurality of page buffers, wherein one of the plurality of page buffers is coupled with one of the plurality of memory sub-planes through a bit line, and each page buffer is configured to sense a fail bit current through the bit line; and
a verify counting circuit coupled with the page buffer array and configured to:
obtain the verify result based on a sum of fail bit currents of the plurality of memory sub-planes; and
determine the number of fail bits of the memory plane based on the verify result.

3. The memory device of claim 2, wherein the verify counting circuit comprises:
a reference current output circuit configured to output at least one reference current; and
a comparator, wherein a first input end of the comparator is coupled with the page buffer array and a second input end of the comparator is coupled with the reference current output circuit, and the comparator is configured to:
compare the at least one reference current and the sum of the fail bit currents; and
output the verify result.

4. The memory device of claim 3, wherein each page buffer is further configured to:
maintain the sensed fail bit current for a preset time period.

5. The memory device of claim 4, wherein the reference current output circuit is configured to output the reference current after the fail bit current has been maintained for the preset time period.

6. The memory device of claim 4, wherein the preset time period comprises 1 microsecond.

7. The memory device of claim 2, wherein the page buffer comprises:
a precharge circuit, wherein a first end of the precharge circuit is coupled with the bit line through a sensing node and a second end of the precharge circuit is coupled with the verify counting circuit.

8. The memory device of claim 1, wherein the memory cell array comprises a plurality of memory planes, and the peripheral circuit is further configured to:
select at least one memory plane from the plurality of memory planes; and
perform the verify operation on the selected memory plane.

9. The memory device of claim 1, wherein the verify operation comprises a program verify operation or an erase verify operation.

10. A method of operating a memory device, comprising:
performing a verify operation on a plurality of memory sub-planes at the same time to obtain a verify result for the memory plane; and
determining a number of fail bits of the memory plane based on the verify result,
wherein the memory device comprises a memory cell array comprising a memory plane, and the memory plane comprises a plurality of memory sub-planes.

11. The method of claim 10, wherein:
the memory device further comprises a plurality of page buffers and a verify counting circuit;
one of the plurality of page buffers is coupled with one of the plurality of memory sub-planes through a bit line; and
performing the verify operation on the plurality of memory sub-planes at the same time to obtain the verify result for the memory plane comprises:
sensing, by each page buffer, a fail bit current through the bit line; and
obtaining, by the verify counting circuit, the verify result based on a sum of fail bit currents of the plurality of memory sub-planes.

12. The method of claim 11, wherein the determining the number of fail bits of the memory plane based on the verify result comprises:
determining, by the verify counting circuit, the number of fail bits of the memory plane based on the verify result.

13. The method of claim 11, wherein the verify counting circuit comprises a reference current output circuit and a comparator, a first input end of the comparator is coupled with the plurality of page buffers, a second input end of the comparator is coupled with the reference current output circuit, and obtaining, by the verify counting circuit, the verify result based on the sum of the fail bit currents of the plurality of memory sub-planes comprises:
outputting, by the reference current output circuit, at least one reference current; and
comparing, by the comparator, the at least one reference current and the sum of the fail bit currents, and outputting the verify result.

14. The method of claim 13, further comprising:
maintaining, by each page buffer, the sensed fail bit current for a preset time period.

15. The method of claim 14, wherein outputting, by the reference current output circuit, the at least one reference current comprises:
outputting, by the reference current output circuit, the reference current after the fail bit current has been maintained for the preset time period.

16. The method of claim 14, wherein the preset time period comprises 1 microsecond.

17. The method of claim 10, further comprising:
selecting at least one memory plane from a plurality of memory planes, and perform the verify operation on the selected memory plane.

18. The method of claim 10, wherein the verify operation comprises a program verify operation or an erase verify operation.

19. A memory system, comprising:
one or more memory devices, wherein each memory device comprises:
a memory cell array comprising a memory plane, wherein the memory plane comprises a plurality of memory sub-planes; and
a peripheral circuit coupled with the memory cell array and configured to:
perform verify operations on the plurality of memory sub-planes at the same time to obtain a verify result for the memory plane; and
determine a number of fail bits of the memory plane based on the verify result; and
a memory controller coupled to the memory devices and configured to control the memory devices.

20. The memory system of claim 19, wherein the peripheral circuit comprises:
a page buffer array comprising a plurality of page buffers, wherein one of the plurality of page buffers is coupled with one of the plurality of memory sub-planes through a bit line, and each page buffer is configured to sense a fail bit current through the bit line; and
a verify counting circuit coupled with the page buffer array and configured to:
obtain the verify result based on a sum of fail bit currents of the plurality of memory sub-planes; and
determine the number of fail bits of the memory plane based on the verify result.
